(19) United States
(12) Patent Application Publication
(10) Pub. No.: US 2014/0023208 A1
(43) Pub. Date: Jan. 23, 2014

(54) DIGITAL AUDIO AMPLIFICATION DEVICE USING HARMONICS AND METHOD THEREOF

(71) Applicants: Jong Hoon Oh, Seoul (KR); Kyung Whoon Cheun, Seoul (KR); Sung Hye Cho, Pohang-si (KR); Woo Suk Lee, Seoul (KR)

(72) Inventors: Jong Hoon Oh, Seoul (KR); Kyung Whoon Cheun, Seoul (KR); Sung Hye Cho, Pohang-si (KR); Woo Suk Lee, Seoul (KR)

(73) Assignee: Pulsus Technology Inc., Pohang-si (KR)

(21) Appl. No.: 13/992,152

(22) PCT Filed: Nov. 30, 2011
(86) PCT No.: PCT/KR2011/009216

§ 371 Date: Sep. 27, 2013

(30) Foreign Application Priority Data
Dec. 7, 2010 (KR) 10-2010-0124539

(51) Int. Cl. H03G 3/20

(52) U.S. Cl. CPC H03G 3/20
USPC 381/107

(57) ABSTRACT

The present invention relates to a digital audio amplification device using harmonics and a method thereof, and more specifically, the invention differentially generates characteristics of harmonics (for instance, amplitude or frequency components of harmonics) of an audio signal in order to compensate the audio signal that exceeds a preset threshold value according to the amplitude and characteristics of the audio signal, if the audio signal exceeds the preset threshold value, thereby easily improving the amplitude and the pitch of audio during digital audio amplification.

### FIELD OF THE INVENTION

The present invention relates to a digital audio amplification apparatus using harmonics and a method thereof, and more particularly, to a digital audio amplification apparatus using harmonics and a method thereof, which can easily improve the amplitude and pitch of the audio, by differentially generating the characteristics of harmonics (for example, the amplitude or frequency component of harmonics) of an audio signal in order to compensate for the audio signal exceeding a preset threshold value according to the amplitude and characteristics of the audio signal when the audio signal exceeds the preset threshold value.

### BACKGROUND OF THE INVENTION

In an audio device, the maximum signal amplitude of an output audio signal, which can be output while a distortion rate of the output audio signal is maintained below a constant level, is called maximum output. The maximum signal amplitude is used as an indicator of the performance of the audio device.

When the output audio signal obtained by processing or amplifying an input audio signal is amplified to exceed the maximum output, a signal with amplitude larger than the maximum output is subject to distortion. Due to the distortion, a harmonic signal is generated. At this time, harmonic signals generated according to the system characteristics of an analog amplifier and a digital amplifier may have different audio amplitudes and characteristics.

At this time, a digital audio amplifier system mainly generates odd-order harmonics due to its characteristics. Such odd-order harmonic signal causes dissonances, resulting in a change in the musical characteristics of sound output from the digital audio amplifier system.

Meanwhile, some tube amplifiers or analog amplifier systems may generate even-order harmonics due to their characteristics. Since this may generate an integer times of a scale (octave), output sound becomes richer while maintaining musical characteristics. That is, even though the sum of the amplitudes of all harmonics generated due to distortion is constant, tones and musical meanings may be changed according to generated harmonics. Therefore, the output characteristics of audio actually recognized by a user may be changed.

Furthermore, in order to take full advantage of the output range of an audio device, a user is able to amplify sound over the maximum output range in most audio devices. However, the distortion generated when amplifying the sound over the maximum output range may cause noises that are harsh to the ears of a user. When amplifying an audio signal over the maximum output, an audio device may generate distortion due to its characteristics.

Meanwhile, according to a conventional audio signal processing scheme, an audio signal is amplified within a maximum threshold value using an AGL (Auto Gain Limiter)/AGC (Auto Gain Control) technology. The AGL/AGC technology reproduces an audio signal by taking full advantage of an operational range of an audio device. However, since final gain (Gain) applied to audio signal output is changed according to the amplitude of an original audio signal, it is disadvantageous that the ratio of the relative amplitude of the audio signal is changed over time.

### DETAILED DESCRIPTION OF THE INVENTION

### Technical Problem

The present invention has been made in order to solve the above problems occurring in the related art, and is intended to provide a digital audio amplification apparatus using harmonics and a method thereof, which can easily improve the amplitude and pitch of the audio, by differentially generating the characteristics of harmonics (for example, the amplitude or frequency component of harmonics) of an audio signal in order to compensate for the audio signal exceeding a preset threshold according to the amplitude and characteristics of the audio signal when the audio signal exceeds the preset threshold value.

### Technical Solution

According to an aspect of the present invention, there is provided a digital audio amplification apparatus using harmonics comprising:

a gain adjustment unit configured to adjust a gain of an input audio signal through gain adjustment by a user;

an audio characteristic analysis unit configured to analyze a amplitude and characteristics of the gain-adjusted audio signal, and to check whether the gain-adjusted audio signal is maintained within a preset threshold value; and

a harmonic generation unit configured to differentiate amplitudes of harmonics of the gain-adjusted audio signal or differentially generate frequency components of the harmonics of the gain-adjusted audio signal, and to add the generated harmonics to the gain-adjusted audio in order to compensate for the amplitude of the audio signal exceeding the threshold value according to the amplitude and characteristics of the gain-adjusted audio signal when the gain-adjusted audio signal exceeds the threshold value.

According to another aspect of the present invention, there is provided a digital audio amplification apparatus using harmonics comprising:

a gain adjustment unit configured to adjust a gain of an input audio signal through gain adjustment by a user;

an audio amplitude comparison unit configured to compare a amplitude of the gain-adjusted audio signal with a preset threshold value, and to generate an auto gain value so that the gain-adjusted audio signal is maintained within the preset threshold value;

an auto gain application unit configured to apply the generated auto gain value to the gain-adjusted audio; and

a harmonic generation unit configured to check an attenuation result of the audio signal to which the auto gain has been applied based on the generated auto gain value, to differentially generate harmonics of the audio signal to which the auto gain has been applied, and to add the generated harmonics to the audio signal to which the auto gain has been applied.

According to another aspect of the present invention, there is provided A digital audio amplification method using harmonics comprising:

a gain adjustment step of adjusting a gain of an input audio signal through gain adjustment by a user;

an audio characteristic analysis step of analyzing a amplitude and characteristics of the gain-adjusted audio signal, and checking whether the gain-adjusted audio signal is maintained within a preset threshold value;

a harmonic generation step of differentially generating amplitudes or frequency components of harmonics of the gain-adjusted audio signal in order to compensate for the amplitude of the audio signal exceeding the threshold value according to the amplitude and characteristics of the gain-adjusted audio signal when the gain-adjusted audio signal exceeds the threshold value; and

an audio output step of adding the differentially generated harmonics to the gain-adjusted audio and outputting the audio.

According to another aspect of the present invention, there is provided a digital audio amplification method using harmonics comprising:

a gain adjustment step of adjusting a gain of an input audio signal through gain adjustment by a user;

an audio gain generation step of comparing a amplitude of the gain-adjusted audio signal with a preset threshold value, and generating an auto gain value so that the gain-adjusted audio signal is maintained within the preset threshold value;

an auto gain application step of applying the generated auto gain value to the gain-adjusted audio;

an attenuation result check step of checking an attenuation result of the audio signal to which the auto gain has been applied based on the generated auto gain value;

a harmonic generation step of differentially generating harmonics of the audio signal to which the auto gain has been applied based on the checked attenuation result; and

an audio output step of adding the differentially generated harmonics to the audio signal to which the auto gain has been applied, and outputting the audio signal.

### Advantageous Effects

According to the present invention, when an audio signal exceeds a preset threshold value, the characteristics (for example, the amplitudes or frequency components of harmonics) of an audio signal exceeding the preset threshold value are differentially generated in order to compensate for the audio signal according to the amplitude and characteristics of the audio signal, so that it is possible to easily improve the amplitude and pitch of the audio during digital audio amplification.

Furthermore, according to the present invention, when an audio signal is amplified over maximum output, distortion generated according to the characteristics of an audio device is adjusted according to distortion components desired by a user, so that it is possible to compensate for the audio signal through the adjusted distortion.

Furthermore, according to the present invention, noises generated according to a change in the ratio of a relative amplitude of an audio signal over time by AGL/AGC used in audio signal processing are adjusted using harmonics, so that it is possible to supplement the amplitude and characteristics of the audio.

### BRIEF DESCRIPTION OF DRAWINGS

FIG. 1 is a configuration diagram of a digital audio amplification apparatus using harmonics in accordance with a first embodiment of the present invention.

FIG. 2 is a configuration diagram of a digital audio amplification apparatus using harmonics in accordance with a second embodiment of the present invention.

FIG. 3 is a detailed configuration diagram of a first embodiment of a harmonic generation unit of FIG. 2 in accordance with the present invention.

FIG. 4 is a detailed configuration diagram of a second embodiment of a harmonic generation unit of FIG. 2 in accordance with the present invention.

FIG. 5 is a flowchart of a first embodiment of a digital audio amplification method using harmonics in accordance with the present invention.

FIG. 6 is a flowchart of a second embodiment of a digital audio amplification method using harmonics in accordance with the present invention.

### DESCRIPTION OF THE MAIN REFERENCE NUMERALS IN DRAWINGS

100: DIGITAL AUDIO AMPLIFICATION APPARATUS
110: GAIN ADJUSTMENT UNIT
120: AUDIO CHARACTERISTIC ANALYSIS UNIT
130: HARMONIC GENERATION UNIT
210: GAIN ADJUSTMENT UNIT
220: AUTO GAIN APPLICATION UNIT
230: AUDIO AMPLITUDE COMPARISON UNIT
240: HARMONIC GENERATION UNIT
310: COEFFICIENT SELECTION DETERMINATION SECTION
320: POLYNOMIAL CALCULATION SECTION
410: FREQUENCY CONVERSION SECTION
420: FREQUENCY COMPONENT ANALYSIS SECTION
430: AUDIO CHARACTERISTIC ANALYSIS SECTION
440: DIFFERENTIAL HARMONIC GENERATION SECTION
450: FREQUENCY INVERSE CONVERSION SECTION

### EMBODIMENTS OF THE INVENTION

Hereinafter, embodiment in accordance with the present invention will be described with reference to the accompanying drawings. Constituents of the present invention and effects thereof will be clearly understood according to the following detailed description. Prior to the detailed description of the present invention, for the same constituent, the same reference numerals are used as possible although it is shown on different drawings, and, for the notified constituent, it is noted that concrete description will be omitted when it is determined to obscure the gist of the present invention.

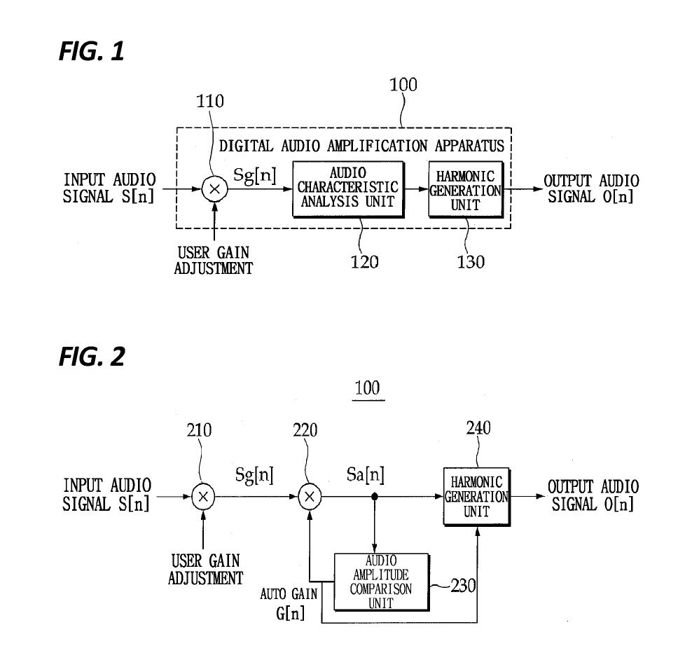

FIG. 1 is a configuration diagram of a digital audio amplification apparatus using harmonics in accordance with a first embodiment of the present invention.

As illustrated in FIG. 1, a digital audio amplification apparatus 100 in accordance with the first embodiment of the present invention includes a gain adjustment unit 110, an audio characteristic analysis unit 120, and a harmonic generation unit 130.

Digital audio amplification apparatus 100 in accordance with the first embodiment of the present invention relates to an apparatus that analyzes the degree by which an audio signal S[n] exceeds a maximum output range when the audio signal is amplified beyond maximum output, and processes the audio signal based on the amplified degree. At this time, in order to substantially avoid distortion generated according to the characteristics of an audio device, digital audio amplification apparatus 100 processes the input audio signal S[n] within the maximum output of the audio device, and amplifies the audio signal. That is, digital audio amplification apparatus 100 generates harmonics desired by a user through the modification of the audio signal within the maximum output range of the audio device, thereby controlling the output characteristics and amplitude of the audio signal while maintaining musical characteristics. Furthermore, digital audio amplification apparatus 100 is able to check the amplitude of the amplified audio signal exceeding the maximum output of the audio device, and to generate harmonics designated by a user according to the amplitude thereof.

Hereinafter, each element of digital audio amplification apparatus 100 in accordance with the first embodiment of the present invention will be described.

Gain adjustment unit 110 receives the audio signal S[n] input into digital audio amplification apparatus 100, and adjusts a gain of the input audio signal S[n] through gain adjustment by a user, and outputs a gain-adjusted audio signal Sg[n]. The gain-adjusted audio signal Sg[n] may be maintained within a preset threshold value according to the gain adjustment by a user, or may exceed the threshold value. Furthermore, gain adjustment unit 110 may adjust the gain of the input audio signal S[n] according to a preset gain adjustment value.

Audio characteristic analysis unit 120 receives the gain-adjusted audio signal Sg[n] from gain adjustment unit 110. Audio characteristic analysis unit 120 analyzes the amplitude and characteristics of the gain-adjusted audio signal Sg[n], and checks whether the audio signal Sg[n] is maintained within the preset threshold value. Based on a result of the check, audio characteristic analysis unit 120 analyzes the degree by which the gain-adjusted audio signal Sg[n] exceeds the preset threshold value. Furthermore, for each sample, audio characteristic analysis unit 120 may measure the degree by which the gain-adjusted audio signal Sg[n] exceeds the preset threshold value.

When the gain-adjusted audio signal Sg[n] exceeds the preset threshold value, harmonic generation unit 130 differentiates the amplitudes of harmonics of the gain-adjusted audio signal Sg[n], and adds the differentiated harmonics to the audio signal Sg[n] so that the amplitude of the audio signal having exceeded the threshold value is compensated according to the amplitude and characteristics of the gain-adjusted audio signal Sg[n]. Furthermore, harmonic generation unit 130 differentially generates frequency components of the harmonics for the gain-adjusted audio signal Sg[n], and adds the frequency components to the gain-adjusted audio signal Sg[n].

FIG. 2 is a configuration diagram of a digital audio amplification apparatus using harmonics in accordance with a second embodiment of the present invention.

As illustrated in FIG. 2, a digital audio amplification apparatus 100 in accordance with the second embodiment of the present invention includes a gain adjustment unit 210, an auto gain application unit 220, an audio amplitude comparison unit 230, and a harmonic generation unit 240.

Gain adjustment unit 210 receives an input audio signal S[n] input to digital audio amplification apparatus 100. Gain adjustment unit 210 adjusts a gain of the input audio signal S[n] through gain adjustment by a user, and outputs a gain-adjusted audio signal Sg[n]. The gain-adjusted audio signal Sg[n] may be maintained within a preset threshold value according to the gain adjustment by a user, or may exceed the threshold value. Furthermore, gain adjustment unit 210 may adjust the gain of the input audio signal S[n] according to a preset gain adjustment value.

Audio amplitude comparison unit 230 compares the amplitude of the gain-adjusted audio signal Sg[n] with the preset threshold value, and generates an auto gain value so that the gain-adjusted audio signal Sg[n] is maintained within the preset threshold value. That is, audio amplitude comparison unit 230 compares the gain-adjusted audio signal Sg[n] with a threshold value designated by a user in realtime, and generates a new auto gain G[n] so that an audio signal above or below the threshold value is output for a predetermined sampling time. The new auto gain G[n] always has a value of 1 or less. That is, audio amplitude comparison unit 230 performs a signal attenuation function so that the audio signal does not exceed the threshold value.

Auto gain application unit 220 applies the auto gain value generated by audio amplitude comparison unit 230 to the input audio. Auto gain application unit 220 may include a multiplier and apply the auto gain value to the input audio. That is, auto gain application unit 220 may generate Sa[n] by re-applying the gain G[n] newly generated by audio amplitude comparison unit 230 to the audio signal Sg[n], and may perform realtime adjustment so that the audio Sa[n] does not exceed the threshold value.

Harmonic generation unit 240 checks an attenuation result of the audio signal Sa[n] to which the auto gain has been applied based on the auto gain value generated by audio amplitude comparison unit 230. Based on the auto gain G[n] generated by audio amplitude comparison unit 230, harmonic generation unit 240 may determine the degree by which the audio signal has been attenuated. Based on the checked attenuation result, harmonic generation unit 240 differentially generates the harmonics of the gain-adjusted audio signal Sa[n], and adds the harmonics to the gain-adjusted audio signal Sa[n]. For example, based on the checked attenuation result, when the attenuation result is equal to or more than a preset attenuation value, harmonic generation unit 240 may increase the amplitudes of the harmonics of the audio signal. Meanwhile, when the attenuation result is less than the preset attenuation value, harmonic generation unit 240 may decrease the amplitudes of the harmonics of the audio signal. That is, when the attenuation degree of the audio signal is large, harmonic generation unit 240 may increase the number of harmonics generated and compensate for the relative loss of sound pressure. Meanwhile, when the attenuation degree of the audio signal is small, harmonic generation unit 240 may decrease the number of harmonics generated and compensate for the relative loss of sound pressure. At this time, harmonic generation unit 240 may adjust harmonics components to generate harmonic components desired by a user, and analyze or generate harmonic components in a time domain or a frequency domain.

As described above, when the gain-adjusted audio signal Sg[n] exceeds the maximum output of the audio device, digital audio amplification apparatus 100 is able to attenuate the audio signal by the degree by which the audio signal exceeds the maximum output and to suppress distortion due to the characteristics of the audio device. Instead, harmonic generation unit 130 is able to differentially generate harmonics according to the degree by which the audio signal exceeds the maximum output, thereby increasing the amplitude of the audio.

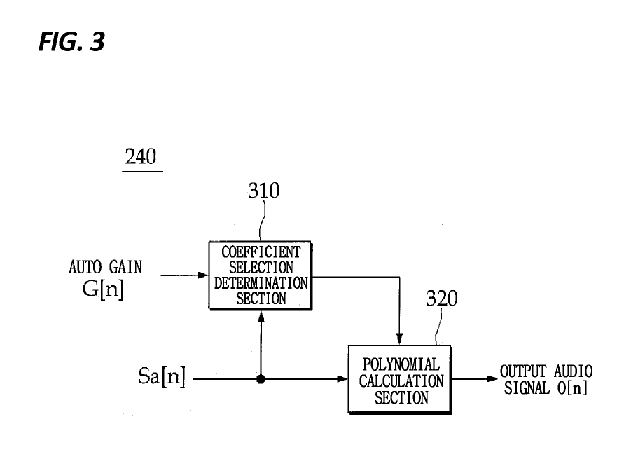

FIG. 3 is a detailed configuration diagram of the first embodiment of harmonic generation unit of FIG. 2 in accordance with the present invention.

As illustrated in FIG. 3, harmonic generation unit 240 of FIG. 2 in accordance with the present invention includes a coefficient selection determination section 310 and a polynomial calculation section 320.

Coefficient selection determination section 310 checks the attenuation result of the audio signal Sa[n], to which the auto gain has been applied, for each audio sample based on the auto gain value generated by audio amplitude comparison unit 230. For each audio sample, coefficient selection determination section 310 selects a coefficient combination corresponding to the attenuation result from coefficient combinations stored in advance in a coefficient table. Furthermore, coefficient selection determination section 310 may store in advance coefficient combinations for the generation of harmonics desired by a user in the coefficient table, and may select the stored coefficient combination at the request by a user. The coefficient table stores the coefficient combinations for generating harmonics, and these coefficient combinations may be changed by a user.

Polynomial calculation section 320 differentially generates the harmonics of the auto gain audio signal Sa[n], to which the auto gain has been applied, for each audio sample using the coefficient combination selected by coefficient selection determination section 310, and adds the harmonics to the auto gain-adjusted audio signal Sa[n]. Polynomial calculation section 320 may perform N-order polynomial calculation for each audio sample Sa[n], and generate a new output audio signal O[n]. At this time, a used coefficient may be changed according to audio samples.

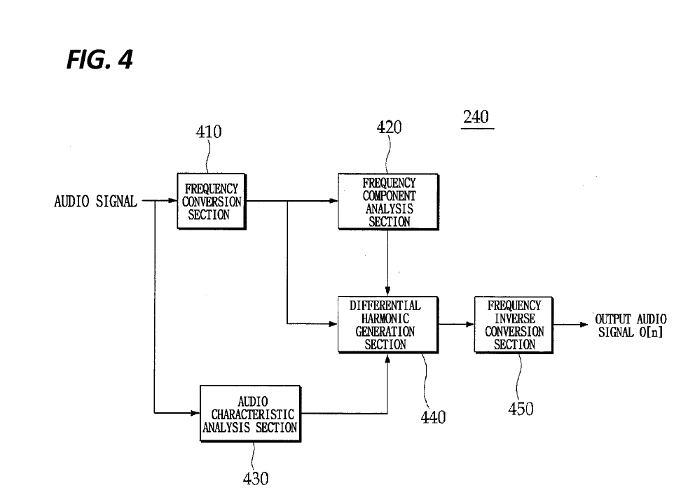

FIG. 4 is a detailed configuration diagram of the second embodiment of the harmonic generation unit of FIG. 2 in accordance with the present invention.

As illustrated in FIG. 4, harmonic generation unit 240 of FIG. 2 in accordance with the present invention includes a frequency conversion section 410, a frequency component analysis section 420, an audio characteristic analysis section 430, a differential harmonic generation section 440, and a frequency inverse conversion section 450.

Frequency conversion section 410 converts the auto gain-adjusted audio signal to a frequency domain.

Frequency component analysis section 420 analyzes frequency components of the audio signal converted to the frequency domain by frequency conversion section 410.

Audio characteristic analysis section 430 analyzes audio characteristics of the auto gain-adjusted audio signal.

Differential harmonic generation section 440 differentially generates harmonics for the auto gain-adjusted audio signal, which has been converted to the frequency domain, based on the audio characteristics analyzed by audio characteristic analysis section 430 and the frequency components analyzed by frequency component analysis section 420, and adds the harmonics to the auto gain-adjusted audio signal converted to the frequency domain. To be specific, based on the audio characteristics analyzed by audio characteristic analysis section 430 and the frequency components analyzed by frequency component analysis section 420, differential harmonic generation section 440 differentially generates even-order harmonics in the frequency domain with respect to a basic frequency of the auto gain-adjusted audio signal. For example, when the basic frequency of the audio signal is 1 kHz, differential harmonic generation section 440 may generate even-order harmonics of 2 kHz, 4 kHz, and so on.

Frequency inverse conversion section 450 inversely converts the audio signal of the frequency domain, which is output from differential harmonic generation section 440, to a time domain, and outputs an audio signal of the time domain.

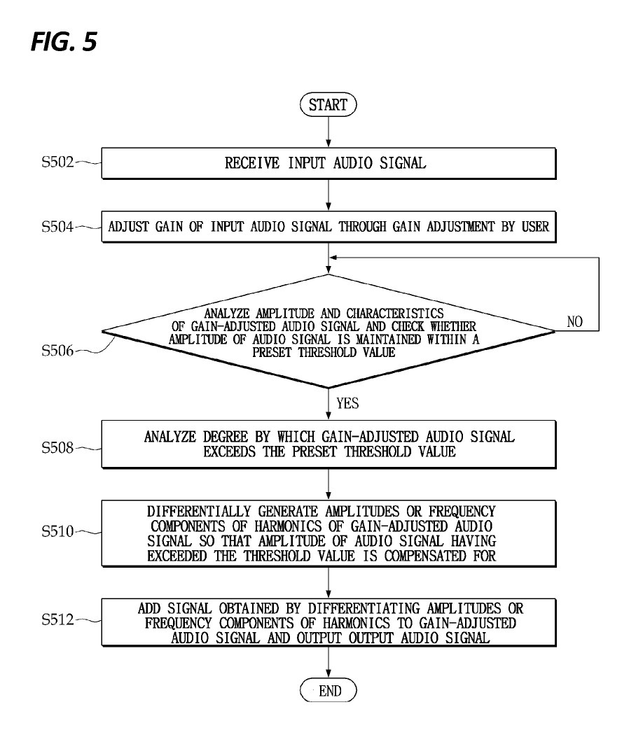

FIG. 5 is a flowchart of the first embodiment of the present invention a digital audio amplification method using harmonics in accordance with.

Gain adjustment unit 110 receives the input audio signal S[n] input to the digital audio amplification apparatus 100 (S502).

Then, gain adjustment unit 110 adjusts the gain of the input audio signal S[n] through gain adjustment by a user, and outputs the gain-adjusted audio signal Sg[n] (S504). Subsequently, audio characteristic analysis unit 120 analyzes the amplitude and characteristics of the audio signal Sg[n], the gain of which has been adjusted by gain adjustment unit 110, and checks whether the audio signal Sg[n] is maintained within the preset threshold value (S506).

Based on the result of the check, when the audio signal Sg[n] exceeds the preset threshold value, audio characteristic analysis unit 120 analyzes the degree by which the gain-adjusted audio signal Sg[n] exceeds the preset threshold value (S508). Meanwhile, when the audio signal Sg[n] does not exceed the preset threshold value, audio characteristic analysis unit 120 performs the process of “S506” of checking the audio signal.

When the gain-adjusted audio signal Sg[n] exceeds the preset threshold value, harmonic generation unit 130 differentially generates the amplitudes or frequency components of the harmonics of the gain-adjusted audio signal Sg[n] so that the amplitude of the audio signal having exceeded the threshold value is compensated according to the amplitude and characteristics of the gain-adjusted audio signal Sg[n] (S510).

Harmonic generation unit 130 adds the signal obtained by differentiating the amplitudes or frequency components of the harmonics of the audio signal Sg[n] to the gain-adjusted audio signal Sg[n], and outputs an output audio signal (S512).

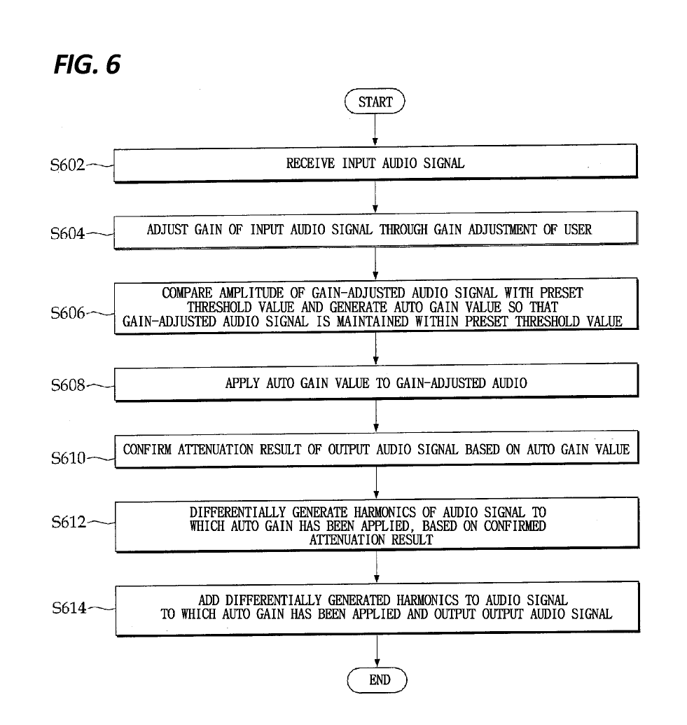

FIG. 6 is a flowchart of the second embodiment of a digital audio amplification method using harmonics in accordance with the present invention.

Gain adjustment unit 210 receives the input audio signal S[n] input to digital audio amplification apparatus 100 (S602).

Then, gain adjustment unit 210 adjusts the gain of the input audio signal S[n] through gain adjustment by a user, and outputs the gain-adjusted audio signal Sg[n] (S604).

Subsequently, audio amplitude comparison unit 230 compares the amplitude of the gain-adjusted audio signal Sg[n] output from gain adjustment unit 210 with the preset threshold value, and generates the auto gain value so that the gain-adjusted audio signal Sg[n] is maintained within the preset threshold value (S606).

Then, auto gain application unit 220 applies the auto gain value generated by audio amplitude comparison unit 230 to the gain-adjusted audio, and outputs the audio signal Sa[n] to which the auto gain has been applied (S608).

Harmonic generation unit 240 check the attenuation result of the audio signal, which is output from the auto gain application unit 220, based on auto gain value generated by the audio amplitude comparison unit 230 (S610). When the attenuation result is equal to or more than the preset attenuation value, harmonic generation unit 240 may increase the amplitudes of the harmonics of the audio signal. Meanwhile, when the attenuation result is less than the preset attenuation value, harmonic generation unit 240 may decrease the amplitudes of the harmonics of the audio signal.

Based on the checked attenuation result, harmonic generation unit 240 differentially generates the harmonics of the audio signal to which the auto gain has been applied (S612).

Harmonic generation unit 240 adds the differentially generated harmonics to the audio signal Sa[n] to which the auto gain has been applied, and outputs the output audio signal O[n] (S614).

So far, the present invention has been described with respect to the exemplary embodiments disclosed above. It can be understood by those skilled in the art that these embodiments may be implemented in modified forms without departing from the essential characteristics of the present invention. Therefore, the disclosed embodiment should be not considered to limit the present invention. The scope of the present invention is determined by the appended claims, and all technologies within a range of equivalent thereto should be construed as being included in the present invention.

In accordance with the present invention, when an audio signal exceeds a preset threshold value, the characteristics of harmonics (for example, the amplitudes or frequency components of harmonics) of an audio signal exceeding the preset threshold value are differentially generated in order to compensate for the audio signal according to the amplitude and characteristics of the audio signal, so that it is possible to easily improve the amplitude and pitch of the audio during digital audio amplification.

1. A digital audio amplification apparatus using harmonics comprising:
a gain adjustment unit configured to adjust a gain of an input audio signal through gain adjustment by a user;
an audio characteristic analysis unit configured to analyze a amplitude and characteristics of the gain-adjusted audio signal, and to check whether the gain-adjusted audio signal is maintained within a preset threshold value; and
a harmonic generation unit configured to differentiate amplitudes of harmonics of the gain-adjusted audio signal or differentially generate frequency components of the harmonics of the gain-adjusted audio signal, and to add the generated harmonics to the gain-adjusted audio in order to compensate for the amplitude of the audio signal exceeding the threshold value according to the amplitude and characteristics of the gain-adjusted audio signal when the gain-adjusted audio signal exceeds the threshold value.

2. A digital audio amplification apparatus using harmonics comprising:
a gain adjustment unit configured to adjust a gain of an input audio signal through gain adjustment by a user;
an audio amplitude comparison unit configured to compare a amplitude of the gain-adjusted audio signal with a preset threshold value, and to generate an auto gain value so that the gain-adjusted audio signal is maintained within the preset threshold value;
an auto gain application unit configured to apply the generated auto gain value to the gain-adjusted audio; and
a harmonic generation unit configured to check an attenuation result of the audio signal to which the auto gain has been applied based on the generated auto gain value, to differentially generate harmonics of the audio signal to which the auto gain has been applied, and to add the generated harmonics to the audio signal to which the auto gain has been applied.

3. The digital audio amplification apparatus using harmonics according to claim 2, wherein the harmonic generation unit checks the attenuation result of the audio signal to which the auto gain has been applied based on the generated auto gain value, increases amplitudes of the harmonics when the checked attenuation result is equal to or more than the preset attenuation value, and decreases the amplitudes of the harmonics when the checked attenuation result is less than the preset attenuation value.

4. The digital audio amplification apparatus using harmonics according to claim 2, wherein the harmonic generation unit comprises:
a coefficient selection determination section configured to check the attenuation result of the audio signal, to which the auto gain has been applied, for each audio sample based on the generated auto gain value, and to select a coefficient combination corresponding to the checked attenuation result from coefficient combinations stored in advance in a coefficient table for the each checked audio sample; and
a polynomial calculation section configured to differentially generate the harmonics of the audio signal, to which the auto gain has been applied, for the each audio sample through polynomial calculation using the selected coefficient combination.

5. The digital audio amplification apparatus using harmonics according to claim 4, wherein the coefficient selection determination section stores in advance user coefficient combinations for generation of harmonics desired by the user in the coefficient table, and selects the user coefficient combination according to a request of the user.

6. The digital audio amplification apparatus using harmonics according to claim 2, wherein the harmonic generation unit comprises:
a frequency conversion section configured to convert the gain-adjusted audio signal to a frequency domain;
an audio characteristic analysis section configured to analyze audio amplitude and characteristics of the gain-adjusted audio signal;
a frequency component analysis section configured to analyze frequency components for the audio signal in the frequency domain, the audio signal being converted to the frequency domain;
a differential harmonic generation section configured to differentially generate harmonics for the converted audio signal based on the analyzed audio amplitude and characteristics and the analyzed frequency components, and to add the generated harmonics to the converted audio signal; and
a frequency inverse conversion section configured to inversely convert the audio signal in the frequency domain, which is output from the differential harmonic generation section, to a time domain.

7. The digital audio amplification apparatus using harmonics according to claim 6, wherein the differential harmonic generation section differentially generates even-order harmonics with respect to a fundamental frequency of the converted audio signal based on the analyzed audio amplitude and characteristics and the analyzed frequency components.

8. A digital audio amplification method using harmonics comprising:
a gain adjustment step of adjusting a gain of an input audio signal through gain adjustment by a user;
an audio characteristic analysis step of analyzing a amplitude and characteristics of the gain-adjusted audio signal, and checking whether the gain-adjusted audio signal is maintained within a preset threshold value;
a harmonic generation step of differentially generating amplitudes or frequency components of harmonics of the gain-adjusted audio signal in order to compensate for the amplitude of the audio signal exceeding the threshold value according to the amplitude and characteristics of the gain-adjusted audio signal when the gain-adjusted audio signal exceeds the threshold value; and
an audio output step of adding the differentially generated harmonics to the gain-adjusted audio and outputting the audio.

9. A digital audio amplification method using harmonics comprising:
a gain adjustment step of adjusting a gain of an input audio signal through gain adjustment by a user;
an audio gain generation step of comparing a amplitude of the gain-adjusted audio signal with a preset threshold value, and generating an auto gain value so that the gain-adjusted audio signal is maintained within the preset threshold value;
an auto gain application step of applying the generated auto gain value to the gain-adjusted audio;
an attenuation result check step of checking an attenuation result of the audio signal to which the auto gain has been applied based on the generated auto gain value;
a harmonic generation step of differentially generating harmonics of the audio signal to which the auto gain has been applied based on the checked attenuation result; and
an audio output step of adding the differentially generated harmonics to the audio signal to which the auto gain has been applied, and outputting the audio signal.

10. The digital audio amplification method using harmonics according to claim 9, wherein, in the harmonic generation step, when the checked attenuation result is equal to or more than the preset attenuation value, amplitudes of the harmonics are increased, and when the checked attenuation result is less than the preset attenuation value, the amplitudes of the harmonics are decreased.

11. The digital audio amplification method using harmonics according to claim 9, wherein the harmonic generation step comprises:
a coefficient selection determination step of selecting a coefficient combination corresponding to the checked attenuation result from coefficient combinations stored in advance in a coefficient table for each audio sample checked in the attenuation result check step; and
a polynomial calculation step of differentially generating the harmonics of the audio signal, to which the auto gain has been applied, for each audio sample through polynomial calculation using the selected coefficient combination.

12. The digital audio amplification method using harmonics according to claim 11, wherein, in the coefficient selection determination step, a user coefficient combination for generation of harmonics desired by the user is selected from the coefficient table.

13. The digital audio amplification method using harmonics according to claim 9, wherein the harmonic generation step comprises:
a frequency conversion step of converting the gain-adjusted audio signal to a frequency domain;
an audio characteristic analysis step of analyzing audio amplitude and characteristics of the gain-adjusted audio signal;
a frequency component analysis step of analyzing frequency components for the audio signal in the frequency domain, the audio signal being converted to the frequency domain;
a differential harmonic generation step of differentially generating harmonics for the converted audio signal based on the analyzed audio amplitude and characteristics and the analyzed frequency components, and adding the harmonics to the converted audio signal; and
a frequency inverse conversion step of inversely converting the audio signal of the frequency domain, which is obtained in the differential harmonic generation step, to a time domain.

14. The digital audio amplification method using harmonics according to claim 13, wherein, in the differential harmonic generation step, even-order harmonics with respect to a fundamental frequency of the converted audio signal are differentially generated based on the analyzed audio amplitude and characteristics and the analyzed frequency components.
